(19) United States
(12) Patent Application Publication
(10) Pub. No.: US 2026/0104758 A1
(43) Pub. Date: Apr. 16, 2026

(54) Haptic Actuator and Display Device Including the Same

(71) Applicant: LG Display Co., Ltd., Seoul (KR)

(72) Inventors: Kyung-Yeol Ryu, Paju-si (KR); Seung-Hyun Sung, Paju-si (KR)

(21) Appl. No.: 19/303,000

(22) Filed: Aug. 18, 2025

(30) Foreign Application Priority Data
Oct. 15, 2024 (KR) 10-2024-0140621

(51) Int. Cl. G06F 3/01; H10N 30/20; H10N 30/853; H10N 30/88

(52) U.S. Cl. CPC G06F 3/016; H10N 30/2023; H10N 30/853; H10N 30/883

(57) ABSTRACT

A haptic actuator and a display device including the same are provided. The haptic actuator includes a reinforcing component where a supporter extends downwardly from a long side of a body with a rectangular plane shape arranged on a piezoelectric element. A cavity is positioned along the relatively long side of the reinforcing component. Vibrations generated in the piezoelectric element can be transferred efficiently to the cavity positioned along the long side of the reinforcing component.

### CROSS-REFERENCE TO RELATED APPLICATION

This application claims priority under 35 U.S.C. § 119 (a) to the Korean Patent Application No. 10-2024-0140621, filed in the Republic of Korea on Oct. 15, 2024, the entire contents of which are hereby expressly incorporated by reference into the present application.

### TECHNICAL FIELD

The present disclosure relates to a haptic actuator, and more particularly to, a haptic actuator that can transfer efficiently a vibration from a piezoelectric element and a display device including the haptic actuator.

### BACKGROUND

A touch interface has been applied to mobile electronic devices such as a smartphone, a table PC and a lap-top computer. Haptic technologies providing a use with a touch associated with the touch interface for augmenting user experiences have been attracted attentions. The electronic devices that use haptic technologies can provide users with a more realistic touch interface than conventional electronic devices.

A vibration motor is known as a haptic device that provides a sense of touch to the user. The size or dimension of the module that constitute the electronic devices must be increased in order to drive the vibration motor. As the overall size of the electronic devices to which the vibration motor is applied increases, there is a limit to decrease the size of the electronic devices. In addition, the vibration motor method as the haptic technology only implements a simple vibration effect that shakes the entire electronic devices, and it is difficult to provide various feedbacks to the user.

Other haptic technologies applied to the electronic devices implements ‘dot’ vibrations, so the vibration generation area is narrow. Accordingly, it has the disadvantage of being difficult to apply to mobile devices whose size is gradually increasing. In order to solve these problems, the proposed haptic technologies have a very complex structure, so not only does it require a separate member, but also has the problem that the vibration is concentrated in a specific area.

### SUMMARY OF THE DISCLOSURE

Accordingly, one or more embodiments of the present disclosure are directed to a display device that substantially obviates one or more of the problems due to the limitations and disadvantages of the related art.

An aspect of the present disclosure is to provide a haptic actuator capable of efficiently transferring vibration by expanding a vibration generation area and a display device including the same.

Another aspect of the present disclosure is to provide a haptic actuator that can be easily manufactured using a simple structure and can implement various feedbacks without using other element and a display device including the same.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, the present disclosure provides a haptic actuator that comprises a piezoelectric element having a hexahedron shape; and a reinforcing component arranged on the piezoelectric element, wherein the reinforcing component includes a body having a rectangular plane shape having a first side and a second side adjacent to the first side and with a length shorter than a length of the first side, and arranged on an upper surface of the piezoelectric element; and a supporter extending downwardly from the first side of the body.

The supporter can include a connecting portion extending downwardly from the first side; and a supporting portion extending outwardly from the connecting portion.

In one embodiment, the connecting portion can have a cross-sectional shape inclined outwardly.

As an example, the connecting portion can have the cross-sectional shape inclined outwardly with an angle between about 30° and about 60°.

In another embodiment, the length of the first side can be about two to about five times longer than the length of the second side.

The reinforcing component can include a metallic material.

In one embodiment, the piezoelectric element can include a vibrator in a form of a single-layer thin film; and an electrode connected to one side of the vibrator.

The vibrator can include an electroactive material or a piezoelectric ceramic material.

As an example, the electroactive material can include a material selected from the group consisting of a silicone-containing resin, an acryl-containing resin, a urethane-containing resin, a natural reinforced rubber, polyvinylidene fluoride (PVDF), a polyvinylidene fluoride-trifluoroethylene copolymer (P(VDF-TrFE)) and combinations thereof.

The piezoelectric ceramic material can include a material selected from the group consisting of lead zirconate titanate (PZT), titanate zirconate modified zirconium, barium titanate (BT), lanthanum modified lead barium metaniobate (PBLN), aluminum nitride (AlN), zinc oxide (ZnO) and combinations thereof.

The electrode can include a material selected from the group consisting of carbon grease, a rubber, a metal and combinations thereof.

The piezoelectric element can have a rectangular parallelepiped shape.

In another aspect, the resent disclosure provides a display device that comprises the haptic actuator and a display panel positioned on the haptic actuator.

As an example, the display panel can include a substrate having a pixel area; a light-emitting diode disposed on the substrate; and a touch sensor disposed on the light-emitting diode.

Alternatively or optionally, the display panel can further include a color filter layer disposed on the light-emitting diode; and a thin film transistor disposed on the substrate and electrically connected to the light-emitting diode.

In one or more embodiments, the reinforcing component where the supporter is positioned along the long sides of the body having the rectangular plane shape is arranged on the piezoelectric element having the hexahedral shape such as the rectangular hexahedra shape in the haptic actuator.

The vibration generated form the piezoelectric element having the hexahedral shape can be transferred to the cavity formed by the supporter extended form the rectangular planar body constituting the reinforcing component. By the cavity structure formed by the supporter formed on the long side of the body, the vibration generated from the piezoelectric element can be efficiently transferred to the entire area of the reinforcing component having the supporter with extending longitudinally.

By applying the reinforcing component having the rectangular planar shape, the vibration generated from the piezoelectric element can be transmitted to the entire area of the reinforcing component, not in the form of dot vibration. The vibration area transmitted from the piezoelectric element can be expanded by applying the haptic actuator in accordance with the present disclosure. The display device that provides a more realistic tactile sense to the user can be implemented by applying the haptic actuator in accordance with the present disclosure.

### BRIEF DESCRIPTION OF THE DRAWINGS

The accompanying drawings, which provide a further understanding of the disclosure, are incorporated in and constitute a part of this application, illustrate embodiments of the disclosure and together with the description serve to explain principles of the disclosure.

FIG. 1 illustrates an example exploded perspective view of a haptic actuator in accordance with one or more embodiments of the present disclosure.

FIG. 2 illustrates a schematic perspective view of the haptic actuator in accordance with the present disclosure.

FIG. 3 illustrates a cross-sectional view taken along a line A-A′ in FIG. 2.

FIG. 4 illustrates a cross-sectional view of only a reinforcing component.

FIG. 5 illustrates a cross-sectional view taken along a line B-B′ in FIG. 2 only showing the reinforcing component.

FIG. 6 illustrates a schematic cross-sectional view showing the components of a piezoelectric element in the haptic actuator.

FIG. 7 illustrates a schematic perspective view of a haptic actuator manufactured by Comparative Examples.

FIG. 8 illustrates a cross-sectional view taken along a line C-C′ in FIG. 7

FIG. 9 illustrates a schematic exploded perspective view of a display device including the haptic actuator in accordance with the present disclosure.

FIG. 10 illustrates a schematic cross-sectional view of the display device including the haptic actuator in accordance with the present disclosure.

FIG. 11 illustrates a schematic circuit diagram of a display panel in the display device in accordance with the present disclosure.

FIG. 12 illustrates a schematic cross-sectional view of the display panel in accordance with the present disclosure.

FIGS. 13 to 16 illustrate a graph measuring vibration acceleration in the haptic actuator manufactured in accordance with the present disclosure.

### DETAILED DESCRIPTION OF THE EMBODIMENTS

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing embodiments of the present disclosure are merely illustrative examples, and thus the present disclosure is not limited to the illustrated examples. The same reference numerals refer to the same components throughout this disclosure unless otherwise specified. Further, in the following description of the present disclosure, where a detailed description of a known related art can unnecessarily obscure the gist of the present disclosure, the detailed description thereof can be omitted herein or can be briefly discussed.

Where terms such as “including,” “having,” “comprising,” and the like are used in this disclosure, other parts can be added unless a more limiting term like “only” is used herein. Further, where a component is expressed as being singular, being plural is included, and vice versa, unless otherwise specified.

In analyzing a component, an error range should be interpreted as being included even where there is no explicit description.

In describing a positional relationship, for example, where a positional relationship of two parts/layers is described as being “over,” “on,” “above,” “below,” “under,” “next to,” or the like, one or more other parts/layers can be provided between the two parts/layers, unless a more limiting term like “immediately” or “directly” is used therewith.

When a component or layer is referred to as being “on” another component or layer, it includes both instances where the other component or layer is directly on the other component or layer, or where there is other component or layer intervening therebetween.

In describing a temporal relationship, for example, where a temporal predecessor relationship is described as being “after,” “subsequent,” “next to,” “prior to,” or the like, unless a more limiting term like “immediately” or “directly” is used, cases that are not continuous or sequential can also be included. Further, the term “can” fully encompass all the meanings and coverages of the term “may” and vice versa.

Although the terms first, second, and the like can be used to describe various components, these components are not substantially limited by these terms. These terms are used only to refer to one component separately from another component, and may not define any particular order or sequence. Therefore, a first component described below can substantially be a second component, and vice versa, within the technical spirit of the present disclosure.

Features of various embodiments of the present disclosure can be partially or entirely united or combined with each other, technically various interlocking and driving are possible, and each of the embodiments can be independently implemented with respect to each other or implemented together in a co-dependent relationship.

All the components of each display device according to all embodiments of the present disclosure are operatively coupled and configured.

Reference will now be made in detail to aspects of the disclosure, examples of which are illustrated in the accompanying drawings. Wherever possible, the same reference numbers will be used throughout the drawings to refer to the same or like parts.

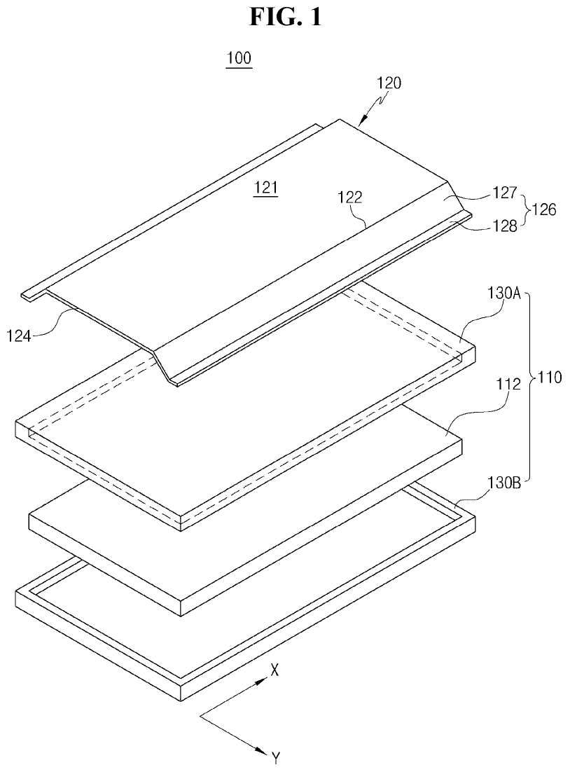

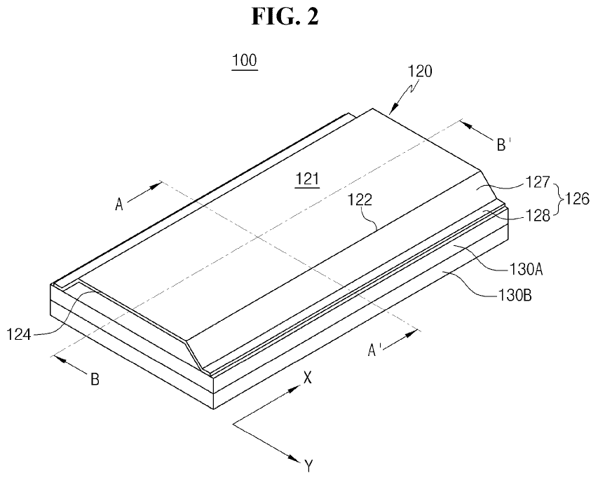

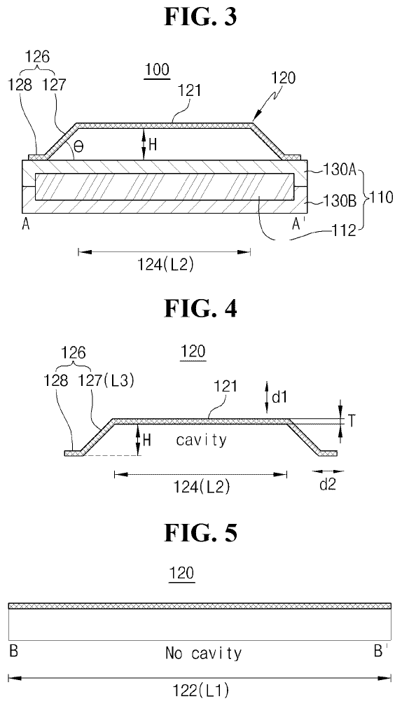

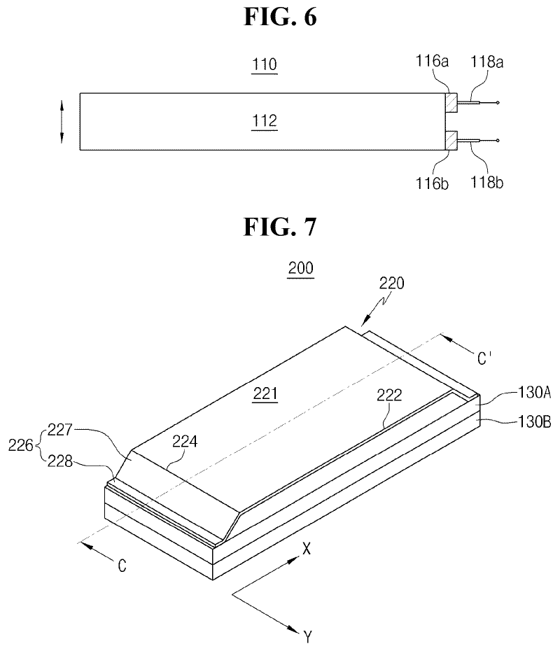

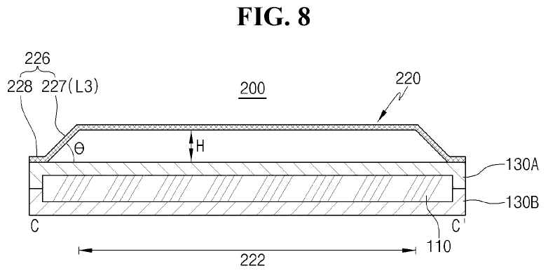

FIG. 1 illustrates an example exploded perspective view of a haptic actuator in accordance with one or more embodiments of the present disclosure. FIG. 2 illustrates a schematic perspective view of the haptic actuator in accordance with the present disclosure. FIG. 3 illustrates a cross-sectional view taken along a line A-A′ in FIG. 2. FIG. 4 illustrates a cross-sectional view of only a reinforcing component. FIG. 5 illustrates a cross-sectional view taken along a line B-B′ in FIG. 2 only showing the reinforcing component.

Referring FIGS. 1 to 5, a haptic actuator 100 in accordance with the present disclosure comprises a piezoelectric element 110 and a reinforcing component 120 arranged on the piezoelectric element 110. The piezoelectric element 110 can have a hexahedral shape, for example, a rectangular hexahedral or parallelepiped shape.

The reinforcing component 120 arranged on the piezoelectric element 110 can have a body 121 having a rectangular planar shape. The rectangular planar shaped body 121 has a first side (long side, long axis) 122 that extends along a first direction (X-axis direction) and facing each other, and a second side (short side, short axis) 124 that extends along a second direction (Y-axis direction) perpendicular to the first direction and facing each other. The first side 122 and the second side 124 define the rectangular planar shape of the body 121. As an example, the body 121 can have a flat upper surface and a flat lower surface.

A reinforcing component having a square shape or a circular dome shape can only receive vibrations in the form of dots or points concentrated in the central area. In contrast, the reinforcing component 120 having the rectangular planar shaped body 121 can efficiently receive vibrations over the entire surface.

The body 121 can have a structure in which the upper surface and the lower surface are substantially flat. If the lower surface of the body 121 is not flat, the processing of the body 121 is difficult, and vibrations generated from the piezoelectric element 110 are not efficiently transmitted, as an additional thick film structure must be formed. In addition, there is a problem in that the vibrations are concentrated only in a specific area (for example, a peripheral area such as an edge).

However, since the body 121 constituting the reinforcing component 120 of the present disclosure is flat on both the upper surface and the lower surface, the body 121 can be easily processed. In addition, since a separate thick film is not required, vibrations generated from the piezoelectric element 110 can be efficiently and uniformly transmitted to the entire reinforcing component 120.

A first length L1 of the first side 122 defining the rectangular planar shaped body 121 is longer than a second length L2 of the second side 124. For example, the first length L1 of the first side 122 can be extended, but is not limited to, by about two to about five times longer than the second length L2 of the second side 124. In one exemplary embodiment, the first length L1 of the first side 122 can be between about 90 mm and about 150 mm, and the second length L2 of the second side 124 can be between about 30 mm and about 50 mm, but is not limited thereto.

A supporter or a supporting member 126 is connected to the first side 122 that defines the body 121 and has the relatively long length L1 and extending downwardly. As the supporter 126 is arranged, the body 121 can be arranged to be spaced apart by a predetermined height H from the upper surface of the piezoelectric element 110. On the other hand, any supporter is not formed on the second side 124 that defines the shaped of the body 121 of the reinforcing component 120 and has the relatively short length L2.

The supporter 126 connected to the first side 122 can include a connecting portion 127 that is extending downwardly from the first side 122 and a supporting portion 128 that is extending outwardly from the connecting portion 127. Accordingly, the body 121 arranged to be spaced apart from the upper surface of the piezoelectric element 110 by the predetermined height H has a cavity that extends long along the first side 122 having the relative long length L1 when viewed from the second side 124 having the relatively short length L2. On the other hand, the body 121 does not have any cavity along the second side 124 having the relatively short length L2 when viewed from the first side 122.

The reinforcing component 120 has the cavity structure extending long along the first side 122 having the relatively long length L1. The vibration generated from the piezoelectric element 110 with the hexahedral shape can be efficiently transmitted to the reinforcing component 120 through the cavity structure extending long along the first side 122.

In an exemplary embodiment, the connecting portion 127 can extend downwardly in a vertical direction with respect to the cross-section of the first side 122 defining the body 121. In another embodiment, the connecting portion 127 can have a cross-sectional shape that extends outwardly as the connecting portion 127 goes downwardly with respect to the cross-section of the first side 122. When the connecting portion 127 has the cross-sectional shape that is inclined toward the outside, the vibration generated in the piezoelectric element 110 can be transmitted to the reinforcing component 120 more efficiently.

In one embodiment, a length L3 of the connecting portion 127 that can have an inclined shape can be between about 3 mm and about 30 mm, for example, about 5 mm and about 20 mm, but is not limited thereto. In another embodiment, the inclined degree θ of the supporter 126 positioned between the connecting portion 127 and the upper surface of the piezoelectric element 110, or a degree between the connecting portion 172 and the cross-section of the body 121 can be, but is not limited to, about 30° to about 60°. In another embodiment, a length of the supporting portion 128 extending to the outside from the terminus of the connecting portion 127 can be, but is not limited to, about 2 mm to about 10 mm.

The connecting portion 127 extends downwardly from the first side 122 defining the plane shape of the body 121, and the supporting portion 128 extends outwardly from the terminus of the connecting portion 127. The supporting portion 128 can be arranged on a peripheral area of the piezoelectric element 110. Accordingly, the body 121 can have the height H spaced apart from the upper surface of the piezoelectric element 110. For example, the height H between the lower surface of the body 120 and the upper surface of the piezoelectric element 110 can be, but is not limited to, about 3 mm to about 7 mm.

The thickness T of the reinforcing component 120, which includes the body 121 and the supporter 126 extending downwardly from the first side 122 that is relatively long among two sides defining the rectangular plane shape of the body 121 can be, but is not limited to, about 0.1 mm to about 1 mm, for example, about 0.1 mm to about 0.5 mm.

In one exemplary embodiment, the reinforcing component 120 can include a metallic material or component. For example, the reinforcing component 120 can include, but is not limited to, a metallic material that can be selected from aluminum, titanium, alloy thereof or combinations thereof.

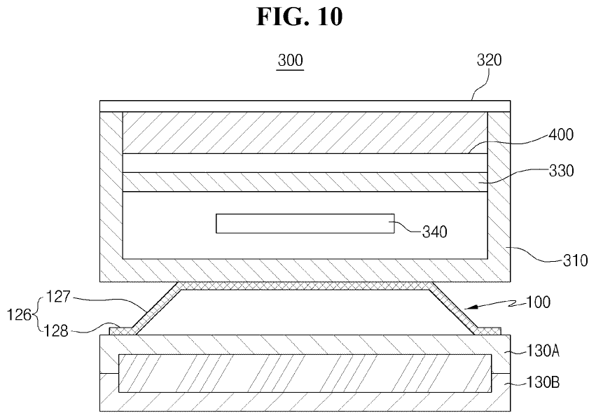

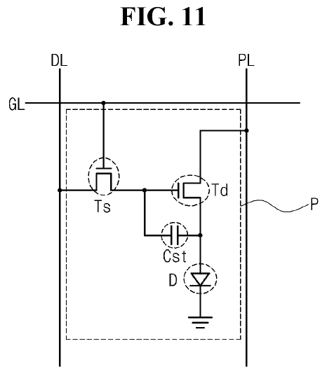

On the other hand, referring to FIGS. 7 and 8, when a haptic actuator 200 includes a reinforcing component 220 having a rectangular planar shaped body 221 defining a long side 222 and a short side 224 and a supporter 226 with a connecting portion 227 connected to the short side 224 and a supporting portion 228, the vibrations generated in the piezoelectric element 110 cannot be transmitted efficiently to the reinforcing component 220.

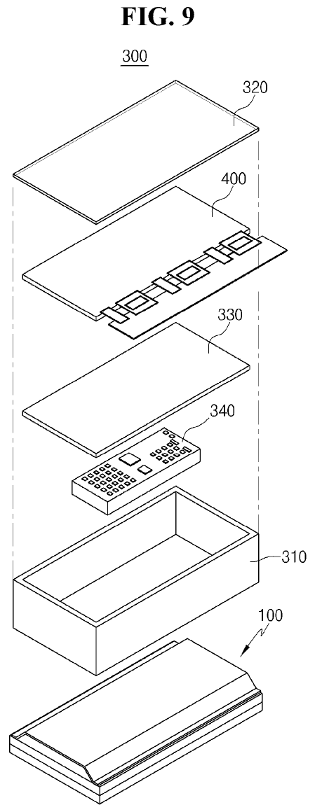

The components in the piezoelectric element 110 will be described in more detail. FIG. 6 illustrates a schematic cross-sectional view showing the components of a piezoelectric element in the haptic actuator.

Referring FIGS. 1 and 6, the piezoelectric element 110 can comprise protecting films 130A and 130B surrounding the vibrator 112. As an example, the protecting film can comprise, but is not limited to, an upper protecting film 130A surrounding the upper sides and the upper surface of the vibrator 112 of the piezoelectric element 110 and a lower protecting film 130B surrounding the lower sides and lower surface of the vibrator 112. For example, the protecting films 130A and 130B can comprise, but is not limited to, a polymer such as polyethylene terephthalate (PET).

The vibrator 112 can have a hexahedral shape, for example, a rectangular hexagonal shape. As an example, the vibrator 112 can have a single-layered thin film shape, and can include an electroactive material or a piezoelectric ceramic material. The electroactive material can be an electroactive polymer.

The electroactive polymers are polymers that can reproducibly exhibit expansion, contraction and bending phenomena by electrical stimulation. Depending on the method of operation, the electroactive polymers can include ionic electroactive polymers (Ionic EAPs) in which the polymer undergoes “contraction-expansion-deformation” by the movement and diffusion of ions, and electronic electroactive polymers (EEPs) in which polarization occurs due to an externally applied electric field and deformation occurs as a result. The electroactive polymer can be an electronic electroactive polymer that has beneficial mechanical properties, high driving forces and durability as well as rapid response velocity.

As an example, the electroactive polymer can include, but is not limited to, a piezoelectric material selected from a silicone-containing resin such as polydimethyl siloxane (PDMS), an acryl-containing resin, a natural reinforced rubber, polyvinylidene fluoride (PVDF), a polyvinylidene fluoride-trifluoro ethylene copolymer (P(VDF-TrFe)), and combinations thereof, and can be processed as a thin film.

The piezoelectric material can comprise, but is not limited to, a material selected from the group consisting of lead zirconate titanate (PZT), titanate zirconate modified zirconium, barium titanate (BT), lanthanum modified lead barium metaniobate (PBLN), aluminum nitride (AlN), zinc oxide (ZnO) and combinations thereof.

In one exemplary embodiment, a first electrode 118a can be connected to an upper side of the vibrator 112 via a first conductive layer 116a and a second electrode 118b can be connected to a lower side of the vibrator via a second conductive layer 116b. For example, each of the first conductive layer 116a and the second conductive layer 116b can comprise, but is not limited to, a high conducive metallic material such as silver (Ag), copper (Cu) and aluminum (Al), respectively. The first and second electrodes 118a and 118b can be connected to external power supply.

As an example, each of the first electrode 118a and the second electrode 118b can comprise, but is not limited to, carbon grease, a rubber, a metal (for example, aluminum, copper and/or silver) and combinations thereof, respectively.

The voltage applied to the piezoelectric element 110 can be about 50 Vp-p to about 200 Vp-p, for example, about 50 Vp-p to about 100 Vp-p, and can be applied to the first and second electrodes 118a and 118b, respectively, including a voltage frequency of about 130 Hz to about 250 Hz. For example, the first and second electrodes 118a and 118b can be formed on one side of the vibrator 112 that may be made of an electroactive material, spaced apart by a predetermined interval, for example, an interval of about 10 mm, but is not limited thereto.

The first and second electrodes 118a and 118b have a potential difference due to the applied voltage, and thus can generate vibration by repeating contraction and expansion. For example, the force of the electric filed for deforming the electroactive material included in the vibrator 112 can be, but is not limited to, about 100 V/μm to about 200 V/μm.

When a driving voltage is applied to the vibrator 112, the electroactive material included in the vibrator 112 contract from a high potential (e.g., ˜10 V) to a low potential (e.g., 0 V) due to the potential difference between the first and second electrodes 118a and 118b. Conversely, when the driving voltage is cut off, the electroactive material becomes a co-potential state and is transformed from the contracted state to an expanded state. As this contraction-expansion occurs continuously, vibration occurs, and the vibration is transmitted to the reinforcing component 120 arranged on the top of the piezoelectric element 110.

In one embodiment, when the voltage is applied to the piezoelectric element 110, the body 121 constituting the reinforcing component 120 arranged on the top of the piezoelectric element 10, and the connecting portion 127 extending downwardly from the first side 122 defining the rectangular planar shape of the body 121 and having the relatively long first length L1 can move in an up-down direction d1 in the cross-section of the piezoelectric element 110. On the other hand, the supporting portion 128, which is the end portion of the reinforcing component 120, is connected to the piezoelectric element 110 by an adhesive or the like. Therefore, the up-down movement of the supporting portion 128 is restricted, and the supporting portion 128 moves in the left-right direction d2 due to the vibration generated in the piezoelectric element 110.

In another embodiment, the operating frequency of the haptic actuator 100 can be about at 130 Hz to about 250 Hz, which is a band of a mechanical receptor that accepts the roughness and smoothness of an object according human senses, but is not limited thereto. When the haptic actuator 100 has a vibration acceleration of 130 Hz to 250 Hz, it includes a response frequency of 130 Hz to 250 Hz in receiving a vibration stimulus from the innermost part of a human skin. Accordingly, various tactile sensations can be fed back to the user according to the contact time or pressure change of the touch input.

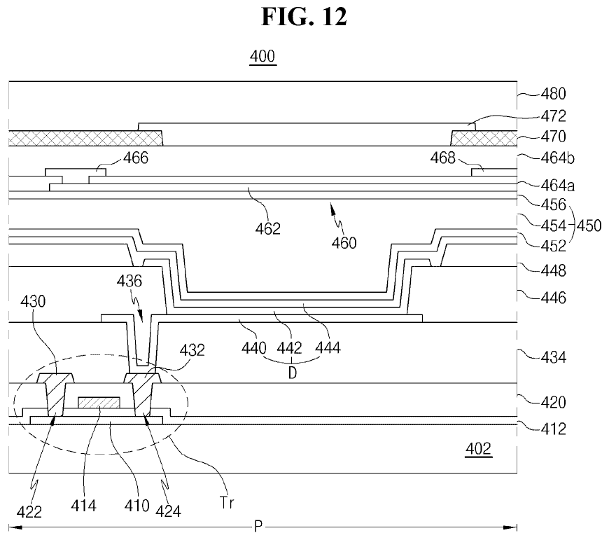

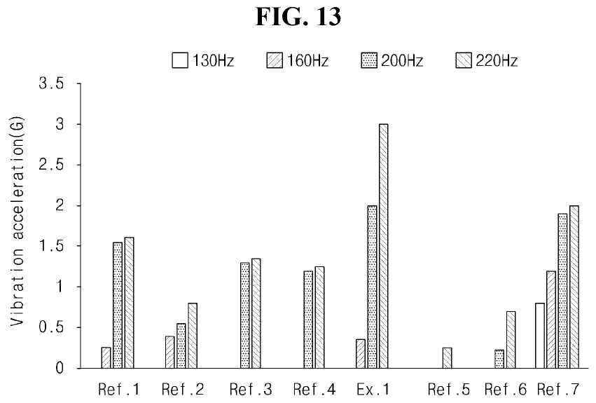

The display device including the haptic actuator in accordance with the present disclosure will be described in more detail. FIG. 9 illustrates a schematic exploded perspective view of a display device including the haptic actuator in accordance with the present disclosure. FIG. 10 illustrates a schematic cross-sectional view of the display device including the haptic actuator in accordance with the present disclosure.

Referring FIGS. 9 and 10, a display device 300 such as a light-emitting display device can comprise the haptic actuator 100 generating the vibration, a lower frame 310 disposed on the haptic actuator 100, a cover window 320 disposed on the opposite side of the lower frame 310, a display panel 400, an inner plate 330 and a driving circuit board 340 disposed sequentially between the lower frame 310 and the cover window 320.

In one embodiment, an air gap can be formed between the cover window 320 and the display panel 400, between the display panel 400 and the inner plate 330, between the inner plate 330 and the driving circuit board 340, and/or between the driving circuit board 340 and the lower frame 310, respectively. Those components or members, and the lower frame and the haptic actuator 100 can be connected or linked to each other using engaging means such as an adhesive and/or a foam tape.

In some embodiments, any one of the adhesive, a tape member, and an adhesive sheet may be interposed between the inner plate 330 and the lower frame 310. For example, an adhesive such an epoxy-containing adhesive, an acrylate-containing adhesive and/or a urethane-containing adhesive may be applied when combining the inner plate 330 and the lower frame 310, or an adhesive may be laminated in advance on the lower surface of the inner plate 330 or the upper surface of the lower frame 310, and then these members may be processed to be combined.

The lower frame 310 may be a cover bottom or a back plate. The lower frame 310 positioned at the rear of the inner plate 330 and/or the driving circuit board 340 has an internal space so that the lower frame 310 can accommodate the display panel 400, the inner plate 330 and the driving circuit board 340. Alternatively, the lower frame 310 can cover at least a part of the sides of the display panel 400 and the inner plate 330.

In one embodiment, the lower frame 310 can comprise a metal material or component. In another embodiment, the lower frame 310 can comprise a fiber so that the lower frame 310 can have a beneficial rigidity. For example, the lower frame 310 can comprise, but is not limited to, at least one of a glass fiber, a carbon fiber, a metallic wire, and a metallic fiber.

The cover window 320 constitutes an outer periphery of the display device 300. The cover window 320 is located outside of the side where the image is displayed on the display panel 400, and transmits the image of the display panel 400 while protecting the display panel 400 from external impact or stress. For example, the cover window 320 can be disposed on an upper surface of the display panel 400.

The cover window 320 can include a reinforced glass or a reinforce plastics. For example, the cover window 320 can comprise, but is not limited to, a material selected from high-strength reinforced glass, polyethylene terephthalate (PET), an acrylic resin such as polymethyl methacrylate (PMMA) and (meth)acrylate-containing resins to prevent scratches from the outside. The cover window 320 may be injection-molded using an in mold lamination method or a co-extrusion method using those materials. When flexible properties are required in the display device 300, the cover window 320 can be manufactured from a plastic material.

The inner plate 330 can be positioned under the display panel 400. The size or dimension of the inner plate 330 can be smaller than the size or dimension of the display panel 400. For example, the inner plate 330 can be attached to a lower surface of the display panel 400 using a double-sided adhesive tape, foam tape, and the like.

In another embodiment, the inner plate 330 can comprise a ferromagnetic material and/or a paramagnetic material. In this case, the inner plate 330 can provide rigidity to the display panel 400. The inner plate 330 can release heat generate in the display panel 400 to the outside.

The inner plate 330 has high heat dissipation properties and can comprise a metal component. For example, the inner plate 330 can comprise aluminum and/or an aluminum alloy. In another embodiment, the inner plate 330 can be configured to include at least one of copper (Cu), silver (Ag), nickel (Ni) and tungsten (W), or can be formed of a heat-dissipating metal plate having an outer surface plated with at least one of nickel (Ni), silver (Ag) and gold (Au).

The driving circuit board 340 can be disposed on a lower surface of the inner plate 330. The inner plate 330 and the driving circuit board 340 are spaced part to constitute an air gap. The air gap may act as an insulating layer that does not transfer heat emitted from the driving circuit board 340 to the display panel 400.

As an example, the driving circuit board 340 can comprise circuit component such as a timing controller. However, the configuration of the driving circuit board 340 is not limited thereto, and may include various circuit components generating signals for driving the display panel 400.

The display panel 400 can be modularized with its edges surrounded by the lower frame 310 and the cover window 330 is arranged on the upper surface of the display panel 400. The display panel 400 may include a substrate, a light-emitting diode, and optionally, a color filter layer and/or a thin film transistor. The display panel 400 of the display device 300 will be described in more detail.

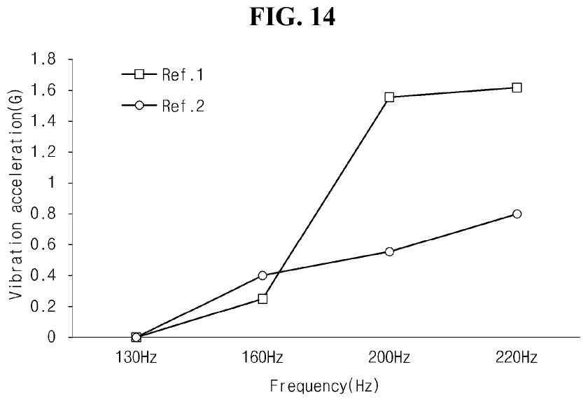

FIG. 11 illustrates a schematic circuit diagram of a display panel in the display device in accordance with the present disclosure.

Referring FIG. 11, the display panel 400 includes a gate line GL, a data line DL, and a power line PL spaced apart parallel to the data line DL or the gate line GL crossing each other to define the pixel region P. A switching thin film transistor Ts, a driving thin film transistor Td, a storage capacitor Cst and a light-emitting diode D can be disposed in the pixel region P. The pixel region P can include a red sub-pixel, a green sub-pixel, a blue sub-pixel and/or a white sub-pixel.

The switching thin film transistor Ts is connected to the gate line GL and the data line DL. The driving thin film transistor Td and the storage capacitor Cst are connected between the switching thin film transistor Ts and the power line PL, and the light-emitting diode D is connected to the driving thin film transistor Td.

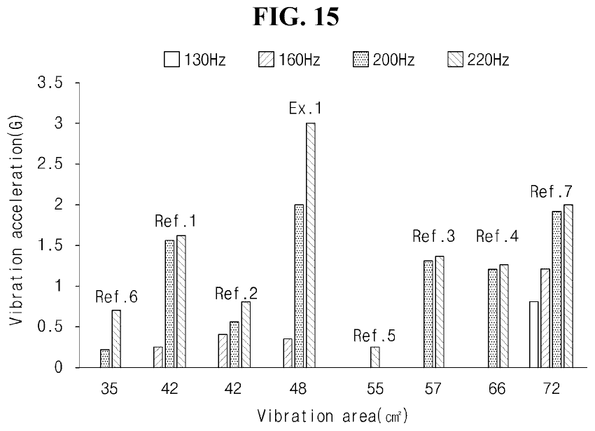

In the display device 300 or the display panel 400, when the switching thin film transistor Ts is turned on by a gate signal applied to the gate line GL, a data signal applied to the data line DL is applied to a gate electrode 414 (FIG. 12) and one electrode of the storage capacitor Cst through the switching thin film transistor Ts.

The driving thin film transistor Td is turned on by the data signal applied to the gate electrode 414 so that a current proportional to the data signal is supplied from the power line PL to the light-emitting diode D through the driving thin film transistor Td. And then, the light-emitting diode D emits light having a luminance proportional to the current flowing through the driving thin film transistor Td. In this case, the storage capacitor Cst is charged with a voltage proportional to the data signal so that the voltage of the gate electrode 414 in the driving thin film transistor Td is kept constant during one frame. Therefore, the display device 100 can display a desired image.

FIG. 12 illustrates a schematic cross-sectional view of the display panel in the display device in accordance with the present disclosure.

Referring FIG. 12, the display panel 400 includes a substrate 402 and a light-emitting diode D disposed on the substrate 402, and optionally a thin film transistor Tr disposed on the substrate 402 and a color filter layer 472 disposed on the light-emitting diode D.

The substrate 402 defines the pixel region P including the red sub-pixel, the green sub-pixel and the blue sub-pixel. Alternatively or additionally, the pixel region P can further comprise the white sub-pixel. The substrate 402 can be a glass substrate and/or a flexible substrate. For example, the substrate 402 can be one of, but is not limited to, a polyimide (PI) substrate, a polyethersulfone (PS) substrate, a polyethylene naphthalate (PEN) substrate, a polyethylene terephthalate (PET) substrate, a polycarbonate (PC) substrate.

The thin film transistor Tr is disposed on the substrate 402. In FIG. 12, the thin film transistor Tr is disposed directly on the substrate 402. Alternatively, a buffer layer is disposed on the substrate 402, and the thin film transistor Tr can be disposed on the buffer layer. For example, the buffer layer can comprise, but is not limited to, inorganic insulating material such as silicon oxide (SiOₓ, wherein 0<x≤2), silicon nitride (SiNₓ, wherein 0<x≤2), and the likes.

The thin film transistor Tr can comprise a semiconductor layer 410, a gate electrode 414, a source electrode 430 and a drain electrode 432. The thin film transistor Tr can be a driving thin film transistor Td (FIG. 11).

The semiconductor layer 410 is disposed on the substrate 402. In one embodiment, the semiconductor layer 410 can comprise oxide semiconductor materials. The oxide semiconductor material can comprise, but is not limited to, zinc oxide (ZnO), indium-zinc oxide (IZO), indium-aluminum-zinc oxide (IAZO), indium-gallium-zinc oxide (IGZO) and/or indium-tin-zinc oxide (ITZO).

When the semiconductor layer 410 includes the oxide semiconductor material, a light-shield pattern can be disposed under the semiconductor layer 410. The light-shield pattern can prevent light from being incident toward the semiconductor layer 410, and thereby, preventing or reducing the semiconductor layer 210 from being degraded by the light.

In another embodiment, the semiconductor layer 410 can comprise polycrystalline silicon. In this case, opposite edges of the semiconductor layer 410 can be doped with impurities.

A gate insulating layer 412 comprising an insulating material is disposed on the semiconductor layer 410 on the entire substrate 402. The gate insulating layer 412 can comprise, but is not limited to, an inorganic insulating material such as silicon oxide (SiOₓ, wherein 0<x≤2) or silicon nitride (SiNₓ, wherein 0<x≤2).

The gate electrode 414 made of a conductive material such as a metal component is disposed on the gate insulating layer 412 so as to correspond to a center of the semiconductor layer 410. For example, the gate electrode 414 can comprise, but is not limited to, metal such as copper (Cu), molybdenum (Mo), titanium (Ti), aluminum (Al), gold (Au) and/or silver (Au). The gate electrode 414 can have a single-layer structure or a multiple-layer structure.

While the gate insulating layer 412 is disposed on the entire area of the substrate 402 in FIG. 12, the gate insulating layer 412 can be patterned identically as the gate electrode 414.

An interlayer insulating layer 420 comprising an insulating material is disposed on the gate electrode 414 and covers an entire surface of the substrate 402. For example, the interlayer insulating layer 420 can comprise, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl. The interlayer insulating layer 420 can have a single-layer structure or a multi-layer structure.

The interlayer insulating layer 420 has first and second semiconductor layer contact holes 422 and 424 that expose or do not cover a portion of the surface nearer to the opposing ends than to a center of the semiconductor layer 410. The first and second semiconductor layer contact holes 422 and 424 are disposed on opposite sides of the gate electrode 414 and spaced apart from the gate electrode 414. The first and second semiconductor layer contact holes 422 and 424 are formed within the gate insulating layer 412 and the interlayer insulating layer 420 in FIG. 12. Alternatively, in certain embodiments, the first and second semiconductor layer contact holes 422 and 424 can be formed only within the interlayer insulating layer 420 when the gate insulating layer 412 is patterned identically as the gate electrode 414.

A source electrode 430 and a drain electrode 432, which are made of conductive material such as a metal, are disposed on the interlayer insulating layer 420. The source electrode 430 and the drain electrode 432 are spaced apart from each other on opposing sides of the gate electrode 414, and contact both sides of the semiconductor layer 410 through the first and second semiconductor layer contact holes 442 and 444, respectively.

For example, each of the source electrode 430 and the drain electrode 432 can comprise, but is not limited to, a metal component such as copper (Cu), molybdenum (Mo), titanium (Ti), aluminum (Al), gold (Au) and/or silver (Ag). Each of the source electrode 430 and the drain electrode 432 can have a single-layer structure or a multi-layer structure.

The semiconductor layer 410, the gate electrode 414, the source electrode 430 and the drain electrode 432 constitute the thin film transistor Tr, which acts as a driving element. The thin film transistor Tr in FIG. 12 has a coplanar structure in which the gate electrode 414, the source electrode 430 and the drain electrode 432 are disposed on the semiconductor layer 410. Alternatively, the thin film transistor Tr can have an inverted staggered structure in which a gate electrode is disposed under a semiconductor layer and a source and drain electrodes are disposed on the semiconductor layer. In this case, the semiconductor layer can comprise amorphous silicon.

A passivation layer 434 is disposed on the source electrode 430 and the drain electrode 432. The passivation layer 434 covers the thin film transistor Tr on the entire substrate 402. The passivation layer 434 has a flat top surface and a drain contact hole (or a contact hole) 436 that exposes or does not cover the drain electrode 432 of the thin film transistor Tr. For example, the passivation layer 434 can comprise, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl.

The light-emitting diode D is disposed on the passivation layer 434. The light-emitting diode D comprises a first electrode 440 that is disposed on the passivation layer 434 and connected to the drain electrode 432 of the thin film transistor Tr. The light-emitting diode D further comprises an emissive layer 442 and a second electrode 444 each of which is disposed sequentially on the first electrode 440. The light-emitting diode D can be disposed in each of the red sub-pixel, the green sub-pixel and the blue sub-pixel, and can emit red color light, green color light and blue color light, respectively.

One of the first electrode 440 and the second electrode 444 can be an anode, and the other of the first electrode 440 and the second electrode 444 can be a cathode. One of the first electrode 440 and the second electrode 444 can be a reflective electrode, and the other of the first electrode 440 and the second electrode 444 can be a transmissive electrode.

The first electrode 440 is disposed separately in each pixel region P. In one embodiment, the first electrode 440 can be an anode and comprise conductive material having relatively high work function value, for example, a transparent conductive oxide (TCO). For example, the first electrode 440 can comprise, but is not limited to, indium-tin-oxide (ITO), indium-zinc-oxide (IZO), indium-tin-zinc-oxide (ITZO), tin oxide (SnO), zinc oxide (ZnO), indium-copper-oxide (ICO) and/or aluminum:zinc oxide (Al:ZnO; AZO).

The first electrode 440 can have a single-layer structure of the transparent conductive oxide. In another embodiment, the first electrode 440 can further comprise a reflective layer so that the first electrode 440 can have a double-layer or a triple-layer structure. The first electrode 440 can be a reflective electrode.

For example, the reflective layer can comprise, but is not limited to, silver (Ag) or an alloy of silver (Ag), and at least one of palladium (Pd), copper (Cu), indium (In) and neodymium (Nd), aluminum-palladium-copper (APC) alloy. As an example, the first electrode 240 can have, but is not limited to, a double-layer structure of Ag/ITO or APC/ITO, or a triple-layer structure of ITO/Ag/ITO or ITO/APC/ITO.

In addition, a bank layer 446 is disposed on the passivation layer 434 in order to cover edges of the first electrode 440. The bank layer 446 exposes or does not cover a center of the first electrode 440 corresponding to the pixel region P. A spacer 448 can be disposed on the bank layer 446. The bank layer 446 and the spacer 448 can comprise the same material. For example, each of the bank layer 446 and the spacer 448 can comprise, but is not limited to, a light-shielding or light-absorbing material.

An emissive layer 442 is disposed on the first electrode 440. In one embodiment, the emissive layer 442 can have a single-layer structure of an emitting material layer (EML). The EML can comprise organic light-emitting materials or inorganic luminescent materials. The display device 300 of the present disclosure can comprise, but is not limited to, an organic light-emitting display device or an inorganic light-emitting display device.

In the organic light-emitting display device, the EML can comprise a host and a dopant as an emitter. In the red sub-pixel, the EML can comprise a red host and a red dopant. In the green sub-pixel, the EML can comprise a green host and a green dopant. In the blue sub-pixel, the EML can comprise a blue host and a blue dopant. In the inorganic light emitting display device, the EML can comprise luminescent particles such as quantum dots (QDs) and quantum rods (QRs).

In another embodiment, the emissive layer 442 can have a multiple-layer structure. For example, the emissive layer 442 can further comprise at least one of a hole injection layer (HIL), a hole transport layer (HTL), an electron blocking layer (EBL) disposed sequentially between the first electrode 440 and the EML, and/or a hole blocking layer (HBL), an electron transport layer (ETL), an electron injection layer (EIL) disposed between the EML and the second electrode 444.

In one embodiment, the light-emitting diode D can emit white color in each of the red sub-pixel, the green sub-pixel and the blue sub-pixel. For example, the emissive layer 442 of the light-emitting diode D can comprise a first emitting part including a first emitting material layer, a second emitting part including a second emitting material layer and a charge generation layer (CGL) disposed between the first emitting part and the second emitting part so that the emissive layer 442 can have a double-stack structure. In this case, one of the first emitting material layer and the second emitting material layer can be a blue emitting material layer, and the other of the first emitting material layer and the second emitting material layer can be a yellow-green emitting material layer, or can comprise a red emitting material layer and a green emitting material layer.

In another embodiment, the emissive layer 442 of the light-emitting diode D can further comprise a third emitting part including a third emitting material layer and a second charge generation layer disposed between the second emitting part and the third emitting part so that the emissive layer 442 can have a triple-stack structure. In this case, the third emitting material layer can be a blue emitting material layer.

The second electrode 444 is disposed on the substrate 402 above which the emissive layer 442 is disposed. The second electrode 444 can be disposed on an emission area. The second electrode 444 can comprise a conductive material with a relatively low work function value compared to the first electrode 440 so that the second electrode 444 can act as a cathode. For example, the second electrode 444 can comprise, but is not limited to, aluminum (Al), magnesium (Mg), calcium (Ca), silver (Ag), and/or alloys thereof, for example, magnesium-silver alloy (Mg:Ag). The second electrode 444 is thin so as to have light-transmissive (semi-transmissive) property.

In addition, an encapsulation layer or an encapsulation film 450 is disposed on the second electrode 444 in order to prevent or reduce outer moisture from penetrating into the light-emitting diode D. For example, the encapsulation layer 450 can have, but is not limited to, a lamination structure of a first inorganic insulating layer 452, an organic insulating layer 454 and a second inorganic insulating layer 456.

For example, each of the first inorganic insulating layer 452 and the second inorganic insulating layer 456 can comprise, but is not limited to, an inorganic insulating material such as silicon oxide (SiOₓ, wherein 0<x≤2) or silicon nitride (SiNₓ, wherein 0<x≤2). For example, the organic insulating layer 454 can comprise, but is not limited to, an organic insulating material such as an epoxy resin, photo-acryl and/or photosensitive acrylic polymer.

The organic insulating layer 454 is disposed between the first inorganic insulating layer 452 and the second inorganic insulating material 456. The organic insulating layer 454 makes a bottom steps flat and provides a flat surface.

A touch sensor 460 comprising a first touch electrode 466 and a second touch electrode 468 can be disposed on the encapsulation layer 450. For example, a connection electrode or a bridge electrode 462 can be disposed on the encapsulation layer 450, a first insulating material layer 464a with first and second contact holes exposing both sides of the connection electrode 462 can be disposed on the connection electrode 462, and the first touch electrode 466 and the second touch electrode 468 can be disposed on the first insulating material layer 464a.

The first touch electrodes 466 disposed adjacently can contact to the connection electrode 462 through the first and second contact holes to be connected electrically to each other. For example, the first insulating material layer 464a can comprise, but is not limited to, an inorganic insulating material such as silicon oxide (SiOₓ, wherein 0<x≤2) or silicon nitride (SiNₓ, wherein 0<x≤2).

A buffer layer can be disposed between the second inorganic insulating layer 456 of the encapsulation layer 450 and the first insulating material layer 464a. For example, the buffer layer can comprise, but is not limited to, an inorganic insulating material such as silicon oxide (SiOₓ, wherein 0<x≤2) or silicon nitride (SiNₓ, wherein 0<x≤2).

A second insulating material layer 464b can be disposed on the first touch electrode 466 and the second touch electrode 468. For example, the second insulating material layer 464b can comprise, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl.

A black matrix 470 and a color filter layer 472 can be disposed on the second insulating material layer 464b. Alternatively, the touch sensor 460 comprising the connection electrode 462, the first insulating material layer 464a, the first touch electrode 466, the second touch electrode 468 and the second insulating material layer 464b can be omitted, and the black matrix 470 and the color filter layer 472 can be disposed on the encapsulation layer 450.

The black matrix 470 is disposed in a non-emission area of an edge of the pixel region P, and has an opening corresponding to the light-emitting diode D. For example, the black matrix 470 can comprise, but is not limited to, a light-shielding or light-absorbing material such as a black resin and/or carbon black.

The color filter layer 472 is disposed in the emission area corresponding to the opening of the black matrix 470. When the pixel region P comprises the red sub-pixel, the green sub-pixel and the blue sub-pixel, the color filter layer 472 can comprise a red color filter pattern corresponding to the red sub-pixel, a green color filter pattern corresponding to the green sub-pixel and a blue color filter pattern corresponding to the blue sub-pixel. The red color filter pattern can comprise at least one of a red dye and a red pigment, the green color filter pattern can comprise at least one of a green dye and a green pigment, and the blue color filter pattern can comprise at least one of a blue dye and a blue pigment.

A passivation layer can be disposed on the second insulating material layer 464b, and the black matrix 470 and the color filter layer 472 can be disposed on the passivation layer. The passivation layer can comprise, but is not limited to, an inorganic insulating material such as silicon oxide (SiOₓ, wherein 0<x≤2) or silicon nitride (SiNₓ, wherein 0<x≤2).

A first insulating layer 480 can be disposed on the color filter layer 472 and the black matrix 470. For example, the first insulating layer 480 can comprise, but is not limited to, an organic insulating material such as epoxy resin and/or photo-acryl. Alternatively, a second insulating layer can be disposed on the first insulating layer 480.

The vibration generated in the haptic actuator 100 is transmitted to the display device 300 so that the user can receive various feedback to the vibration generated in the haptic actuator 100.

Hereinafter, the present disclosure is described in more detail by the exemplary examples, but the present disclosure is not limited to the following examples.

### [Comparative Example 1] (Ref. 1) Manufacturing Haptic Actuator

As illustrated in FIGS. 7 and 8, a reinforcing component made of aluminum was manufactured in which a supporter 226 is connected to extend downwardly from the short side 224 of the body 221 and the cavity is formed along the short side 224. The aluminum thickness was set to 0.2 mm, and the adhesive width between the reinforcing element 220 and the piezoelectric element 110 was set to 5 mm. The supporter 226 extending downwardly was connected to the short side 224 of the body 221 constituting the reinforcing component 200. The length of the long side 222 of the body 221 was set to be 70 mm, the length of the short side 224 was set to be 60 mm, the height H of the body 221 was set to be 5 mm, the length L3 of the connecting portion 227 was set to be 20 mm, the inclination angle θ of the connecting portion 227 was set to be 60°, and the vibration area of the reinforcing component 220 was set to be 40 mm². The reinforcing component 220 was placed on top of the piezoelectric element 110 having a hexagonal shape using an adhesive, and the haptic actuator was manufactured.

### [Comparative Examples 2] to [Comparative Examples 6] (Ref. 2 to Ref. 6) Manufacture of Haptic Actuator

Except for changing the aluminum thickness, adhesive width, length of the connecting portion, and inclination angle of the connection portion, which constitutes the reinforcing component 200, as shown in Table 1 below, the supporter 226 was designed to extend downwardly from the short side 224 of the body 221 so that the cavity was formed along the short side 224, and the reinforcing component 200 was manufacture in the same manner as in Comparative Example 1, and then the component 200 was placed on top of the piezoelectric element 130. In Comparative Example 6, the supporter 226 was connected to both the long side 222 and the short side 224.

### [Comparative Example 7] (Ref. 7) Manufacture of Haptic Actuator

As shown in Table 1 below, except for designing the supporter neither the long side 222 and nor the short side 224 of the body 222 was formed, the reinforcing component 200 was manufacture in the same manner as in Comparative Example 1, and then placed on top of the piezoelectric element to manufacture the haptic actuator 200.

TABLE 1
Shape of Reinforcing Component

| | Al | Adhesive | L3 | Height | Angle | L2 | L1 | Area |
|---|---|---|---|---|---|---|---|---|
| Sample | Thickness(mm) | Width (mm) | (mm) | (mm) | (θ, °) | (mm) | (mm) | (cm²) |
| Ref. 1 | 0.2 | 5 | 20 | 5 | 60 | 60 | 70 | 42 |
| Ref. 2 | 0.5 | 5 | 20 | 5 | 60 | 60 | 70 | 42 |
| Ref. 3 | 0.2 | 5 | 10 | 5 | 30 | 60 | 95 | 57 |
| Ref. 4 | 0.2 | 5 | 5 | 5 | 90 | 60 | 110 | 66 |
| Ref. 5 | 0.2 | 5 | 5 | 5 | 90 | 50 | 110 | 55 |
| Ref. 6 | 0.2 | 5 | 20 & 5 | 5 | 30 & 90 | 50 | 70 | 35 |
| Ref. 7 | 0.2 | — | — | — | — | 60 | 120 | 72 |

### [Example 1] to [Example 4] (Ex. 1 to Ex. 4) Manufacture of Reinforcing Component

A haptic actuator was manufactured by manufacturing the reinforcing component 120 made of aluminum, in which the support 126 is connected and formed along the long side 122 by extending downwardly from the long side 122 of the body 121, and then placing the reinforcing component 120 on top of the piezoelectric element 110. The shapes of the reinforcing component 110 manufacture in Examples 1 to 4 are shown in Table 2 below.

TABLE 2
Shapes of Reinforcing Component

| | Al | Adhesive | L3 | Height | Angle | L2 | L1 | Area |
|---|---|---|---|---|---|---|---|---|
| Sample | Thickness(mm) | Width (mm) | (mm) | (mm) | (θ, °) | (mm) | (mm) | (cm²) |
| Ex. 1 | 0.2 | 5 | 10 | 5 | 30 | 120 | 40 | 48 |
| Ex. 2 | 0.2 | 5 | 10 | 5 | 60 | 120 | 30 | 36 |
| Ex. 3 | 0.2 | 5 | 20 | 5 | 60 | 120 | 30 | 36 |
| Ex. 4 | 0.5 | 5 | 20 | 5 | 60 | 120 | 30 | 36 |

### [Experimental Example 1] Measurement of Vibration Acceleration

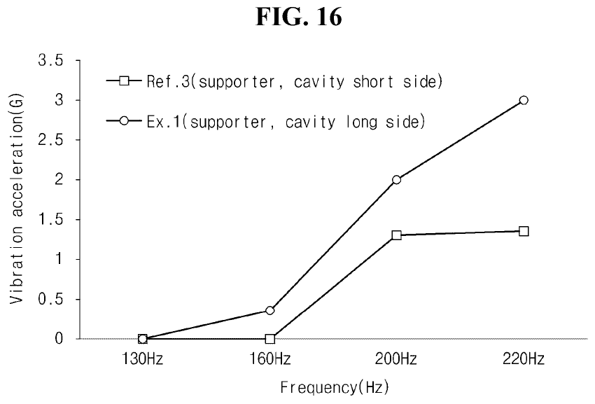

Electrodes were connected to the haptic actuators manufactured in Comparative Examples 1 to 7 and Examples 1 to 4, respectively, and attached to a lower side of the glass, and the a voltage of 60V was applied to measure the vibration acceleration. When the vibration acceleration was less than 10, it was indicated as 0 (zero). The measurement results are shown in Table 3 below and FIGS. 13 to 16.

TABLE 3
Vibration Acceleration of Haptic Actuator

| | Direction of | Vibration | | | | |
|---|---|---|---|---|---|---|
| | supporter & | Area | Vibration Acceleration (Hz) | | | |
| Sample | Cavity | (cm²) | 130 | 160 | 200 | 220 |
| Ref. 1 | Short Side | 42 | 0 | 0.25 | 1.55 | 1.61 |
| Ref. 2 | Short Side | 42 | 0 | 0.40 | 0.55 | 0.8 |
| Ref. 3 | Short Side | 57 | 0 | 0 | 1.3 | 1.35 |
| Ref. 4 | Short Side | 66 | 0 | 0 | 1.2 | 1.25 |
| Ref. 5 | Short Side | 55 | 0 | 0 | 0 | 0.25 |
| Ref. 6 | Short & | 35 | 0 | 0 | 0.22 | 0.7 |
| | Long sides | | | | | |
| Ref. 7 | — | 72 | 0.8 | 1.2 | 1.9 | 2.0 |
| Ex. 1 | Long Side | 48 | 0 | 0.35 | 2.0 | 3 |
| Ex. 2 | Long Side | 36 | 0 | 0.5 | 1.40 | 1.7 |
| Ex. 3 | Long Side | 36 | 0 | 0.4 | 0.8 | 2.1 |
| Ex. 4 | Long Side | 36 | 0 | 0.2 | 1.1 | 1.3 |

As illustrated in Table 3, FIGS. 13 and 16, compared to the haptic actuator manufactured so that the supporter 226 is formed on the short side and the cavity is arranged along the short side as in Comparative Examples 1, 2, 3 and 5, the haptic actuator manufactured so that the support 126 is formed on the long side and the cavity is arranged along the long side, as in Examples 1 to 4, has a small vibration area, but greatly improved vibrated acceleration. As illustrated in FIG. 14, when the thickness of aluminum, a metal component constituting the reinforcing component is increased, the vibration acceleration decreases. As illustrated in FIG. 15, it was confirmed that the vibration area of the reinforcing component is not directly related with the vibration acceleration.

It will be apparent to those skilled in the art that various modifications and variations can be made in the present disclosure without departing from the scope of the disclosure. Thus, it is intended that the present disclosure cover the modifications and variations of the present disclosure provided they come within the scope of the appended claims.

What is claimed is:

1. A haptic actuator, comprising:
a piezoelectric element having a hexahedron shape; and
a reinforcing component arranged on the piezoelectric element,
wherein the reinforcing component includes:
a body having a rectangular plane shape having a first side and a second side adjacent to the first side and with a length shorter than a length of the first side, the body arranged on an upper surface of the piezoelectric element; and
a supporter extending downwardly from the first side of the body.

2. The haptic actuator of claim 1, wherein the supporter includes:
a connecting portion extending downwardly from the first side of the body; and
a supporting portion extending outwardly from the connecting portion.

3. The haptic actuator of claim 2, wherein the connecting portion has a cross-sectional shape inclined outwardly.

4. The haptic actuator of claim 3, wherein the connecting portion has the cross-sectional shape inclined outwardly with an angle between 30° and 60°.

5. The haptic actuator of claim 1, wherein the length of the first side of the body is two to five times longer than the length of the second side.

6. The haptic actuator of claim 1, wherein the reinforcing component includes a metallic material.

7. The haptic actuator of claim 1, wherein the piezoelectric element includes:
a vibrator in a form of a single-layer thin film; and
an electrode connected to one side of the vibrator.

8. The haptic actuator of claim 7, wherein the vibrator includes an electroactive material or a piezoelectric ceramic material.

9. The haptic actuator of claim 8, wherein the electroactive material includes a material selected from the group consisting of a silicone-containing resin, an acryl-containing resin, a urethane-containing resin, a natural reinforced rubber, polyvinylidene fluoride PVDF, a polyvinylidene fluoride-trifluoroethylene copolymer P(VDF-TrFE) and combinations thereof.

10. The haptic actuator of claim 8, wherein the piezoelectric ceramic material includes a material selected from the group consisting of lead zirconate titanate PZT, titanate zirconate modified zirconium, barium titanate BT, lanthanum modified lead barium metaniobate PBLN, aluminum nitride AlN, zinc oxide ZnO, and combinations thereof.

11. The haptic actuator of claim 7, wherein the electrode includes a material selected from the group consisting of carbon grease, a rubber, a metal, and combinations thereof.

12. The haptic actuator of claim 1, wherein the piezoelectric element has a rectangular parallelepiped shape.

13. A display device, comprising:
the haptic actuator of claim 1; and
a display panel positioned on the haptic actuator.

14. The display device of claim 13, wherein the supporter includes:
a connecting portion extending downwardly from the first side of the body; and
a supporting portion extending outwardly from the connecting portion.

15. The display device of claim 14, wherein the connecting portion has a cross-sectional shape inclined outwardly.

16. The display device of claim 15, wherein the connecting portion has the cross-sectional shape inclined outwardly with an angle between about 30° and about 60°.

17. The display device of claim 13, wherein the length of the first side of the body is about two to about five times longer than the length of the second side of the body.

18. The display device of claim 13, wherein the reinforcing component includes a metallic material.

19. The display device of claim 13, wherein the display panel includes:
a substrate having a pixel area;
a light-emitting diode disposed on the substrate; and
a touch sensor disposed on the light-emitting diode.

20. The display device of claim 14, wherein the display panel further includes:
a color filter layer disposed on the light-emitting diode; and
a thin film transistor disposed on the substrate and electrically connected to the light-emitting diode.
